(19) United States
(12) Patent Application Publication
(10) Pub. No.: US 2018/0318799 A1
(43) Pub. Date: Nov. 8, 2018

(54) MULTI-LAYERED WATER-SPLITTING PHOTOCATALYST HAVING A PLASMONIC METAL LAYER WITH OPTIMIZED PLASMONIC EFFECTS

(71) Applicant: SABIC Global Technologies B.V., Bergen op Zoom (NL)

(72) Inventors: Mohd Adnan Khan, Thuwal (SA); Maher Al-Oufi, Thuwal (SA); Hicham Idriss, Thuwal (SA)

(21) Appl. No.: 15/773,376

(22) PCT Filed: Nov. 8, 2016
(86) PCT No.: PCT/IB2016/056726

§ 371 Date: May 3, 2018

Related U.S. Application Data
(60) Provisional application No. 62/255,607, filed on Nov. 16, 2015.

(51) Int. Cl. B01J 23/52; B01J 23/42; B01J 21/06; B01J 21/08; B01J 35/00; B01J 37/02; B01J 19/12; B01J 7/02; C01B 3/04; C23C 14/18; C25B 1/00; C25B 11/04

(52) U.S. Cl. CPC B01J 23/52; B01J 2219/0877; B01J 21/063; B01J 21/08; B01J 35/0006; B01J 35/0013; B01J 35/004; B01J 37/0244; B01J 19/127; B01J 19/123; B01J 7/02; C01B 3/042; C23C 14/185; C25B 1/003; C25B 11/0484; B01J 2219/1203; B01J 2219/0892; B01J 23/42

(57) ABSTRACT

Photocatalysts and methods of using the same for producing hydrogen and oxygen from water are disclosed. The photocatalysts include a photoactive layer having a thickness of 10 nanometers (nm) to 1000 nm and a plasmonic metal layer having a thickness of 2 nm to 20 nm and having surface plasmon resonance properties in response to ultra-violet and/or visible light, wherein the plasmonic metal layer is positioned proximal to the photoactive layer.

### CROSS REFERENCE TO RELATED APPLICATIONS

This application claims the benefit of priority of U.S. Provisional Patent Application No. 62/255,607, filed Nov. 16, 2015, which is hereby incorporated by reference in its entirety.

### BACKGROUND OF THE INVENTION

A. Field of the Invention

The invention generally concerns a multi-layered photocatalyst that can be used to produce hydrogen from water in photocatalytic reactions. The photocatalyst includes a photoactive layer positioned proximal to a plasmonic metal layer, wherein the plasmonic metal layer has a thickness range of 2 nm to 20 nm to optimize its plasmonic resonance properties in response to ultra-violet and/or visible light.

B. Description of Related Art

Hydrogen production from water offers enormous potential benefits for the energy sector, the environment, and the chemical industry (See, for example, Kodama & Gokon, Chem. Rev., 2007, Vol. 107, p. 4048; Connelly & Idriss, Green Chemistry, 2012, Vol. 14, p. 260; Fujishima & Honda, Nature 238:37, 1972; Kudo & Miseki, Chem. Soc. Rev 38:253, 2009; Nadeem, et al., Int. J. Nanotechnology, 2012, Vol. 9, p. 121; Maeda, et al., Nature 2006, Vol. 440, p. 295). While methods currently exist for producing hydrogen from water, many of these methods can be costly, inefficient, or unstable. For instance, photoelectrochemical (PEC) water splitting requires an external bias or voltage and a costly electrode (e.g., Pt-based).

With respect to photocatalytic electrolysis of water from light sources, while many advances have been achieved in this area, most materials are either unstable under realistic water splitting conditions or require considerable amounts of other components (e.g., large amounts of sacrificial hole or electron scavengers) to work, thereby offsetting any gained benefits. By way of example, a semiconductor photocatalyst is a material that can be excited upon receiving energy equal to or higher than its electronic band gap. Upon photo-excitation, electrons are transferred from the valence band (VB) to the conduction band (CB), resulting in the formation of an excited electron (in the CB) and a hole (in the VB). In the case of water splitting, electrons in the CB reduce hydrogen ions to H₂ and holes in the VB oxidize oxygen ions to O₂.

One of the main limitations of most photocatalysts is the fast electron-hole recombination, a process that occurs at the nanosecond scale, while the oxidation-reduction reactions are much slower (microsecond time scale). Many approaches have been conducted in order to design a photocatalyst that can work under direct sun light in stable conditions. Problems associated with these types of systems include light absorption efficiency, charge carrier life time, and materials stability. In order to enhance light absorption, a large number of photocatalysts were designed based on visible light range band gap either by solid solutions, hybrid materials, or doping of wide band gap semiconductors. In order to increase the charge carrier's life time, hydride semiconductors, addition of metal nanoparticles, and the use of sacrificial agents are currently used (See, for example, Connelly et al, Green Chemistry, 2012, Vol. 14, pp. 260-280; Nadeem et al., Int. J. Nanotechnology, Special edition on Nanotechnology in Scotland, 2012, Vol. 9, pp. 121-162; Connelly et al., Materials for Renewable and Sustainable Energy, 2012, Vol. 1, pp. 1-12; Walter et al, Chem. Rev., 2010, Vol. 110, pp. 6446-6473; and Yang et al., Appl. Catal. B: Environmental, 2006, Vol. 67, pp. 217-222). Ultimately, however, over 90% of photo-excited electron-hole pairs disappear/recombine prior to performing the desired water splitting reaction, thereby making the currently available photocatalysts inefficient (See, for example, Yamada, et al., Appl Phys Lett., 2009, Vol. 95, pp. 121112-121112-3).

Over the past several years, it has been recognized that the efficiency of photocatalytic processes can be improved by exploiting the plasmon resonance of silver (Ag) and gold (Au) nanoparticles on top of a semiconductor material. In this regard, several research groups have deposited plasmonic metal nanoparticles on top of TiO₂, and observed enhanced photocatalytic water splitting. For example, Duan et al., “Enhancement of light absorption of cadmium sulfide nanoparticle at specific wave band by plasmon resonance shifts”, Physica E: Low-dimensional Systems and Nanostructures 2011, 43, 1475-1480, reported enhancement for Ag nanoparticles on CdS with a SiO₂ intermediate layer positioned between CdS and Ag. Torimoto et al., “Plasmon-enhanced photocatalytic activity of cadmium sulfide nanoparticle immobilized on silica-coated gold particles,” The Journal of Physical Chemistry Letters 2011, 2, 2057-2062, also demonstrated enhanced photocatalytic activity for photocatalytic water splitting by deposition of CdS on Au/SiO₂ particles. Several studies have focused on finding the optimum Au wt. % in the semiconductors rather than nanoparticle geometry, simply because they are of spherical or hemispherical shape in most cases. In order to enhance the reaction rate, the deposited Au particles have two main functions. First, they pump excited electrons away from the conduction band and therefore reduce hydrogen ions to hydrogen molecules (M. Murdoch, G. W. N. Waterhouse, M. A. Nadeem, M. A. Keane, R. F. Howe, J. Llorca, H. Idriss, Nature Chemistry 3, 489-492 (2011)). Second they enhance the reaction rate due to their plasmonic resonance response. (V. Jovic, K. E. Smith, H. Idriss, G. I. N. Waterhouse, ChemSusChem. 8 (15) 2551-2559 (2015)) In that regard the plasmonic resonance response is viewed as an enhancement of the electric field around the semiconductor and therefore is poised to increase the lifetime of charge carriers. It is however to be noticed that the enhancement of the field is felt at a short range (few nm) (S. Linic, P. Christopher, D. B. Ingram, Nature Materials, 10, 911-921).

The current attempts to exploit plasmon resonance properties of various metals such as silver (Ag) and gold (Au) have focused on particle morphology as well as wt. % of the particles in relation to the overall weight of the photocatalyst. While incremental increases in photactive efficiency has been observed, the current photocatalysts remain largely inefficient for large-scale commercial use.

### SUMMARY OF THE INVENTION

A solution to the aforementioned inefficiencies surrounding current water-splitting photocatalysts has been discovered. The solution resides in optimizing the localized surface plasmonic resonance (LSPR or plasmonic resonance) effects of plasmonic metals (e.g., gold, silver, or copper, or any combination or alloy thereof). In particular, it has been discovered that the LSPR/plasmonic resonance properties of plasmonic metals can be optimized if the metals are used as films or layers rather than as particles, where the films or layers have a thickness range of 2 nanometers (nm) to 20 nm. This thickness range results in optimal hydrogen production during water splitting reactions. In preferred instances, the thickness range of the plasmonic metal layer is 4 nm to 12 nm, more preferably 6 nm to 10 nm, or most preferably from 7 nm to 9 nm or about 8 nm. Without wishing to be bound by theory, it is believed that when the plasmonic metal layer has this thickness range, the resulting electric field produced by this layer is increased or optimized when subjected to ultraviolet (280-400 nm) and/or visible light (400 to 700 nm). A non-limiting example of this optimization effect is illustrated in FIG. 9. It is believed that the most preferred thickness range of 7 nm to 9 nm results, in part, from the formation of a discontinuous plasmonic metal layer having a plurality of noncontiguous layer or coating regions. With that said, enhancement or optimization of the plasmonic properties of the metal layer is still observed when then layer is a continuous layer (e.g., when the layer has a thickness of 10 nm to 20 nm). When the plasmonic metal layer is placed proximal to a photoactive layer (e.g., layer comprising titanium dioxide (TiO₂), zinc oxide (ZnO), or cadmium sulfide CdS), the increased electric field assists in the promotion of excited electrons and holes to the surface of the photoactive layer. These electrons and holes can then participate in the oxidation/reduction reaction of water rather than recombining with one another. Stated another way, the enhanced electric field effect increases the charge carrier life time and reduces the likelihood of an electron-hole recombination event from occurring. An added advantage of this increase in charge carrier life time is that the use of doping agents (e.g., nitrogen or sulfur doping agents), conductive metal nanoparticles, and/or sacrificial agents can be further reduced or eliminated altogether, thereby further increasing the efficiency of the photocatalysts of the present invention from a cost perspective.

In one aspect of the present invention there is disclosed a multi-layered photocatalyst comprising a photoactive layer having a thickness of 10 nanometers (nm) to 1000 nm and a plasmonic metal layer having a thickness of 2 nm to 20 nm and having surface plasmon resonance properties in response to ultra-violet and/or visible light. The terms “layer” and coating” can be used interchangeably throughout the specification. Plasmonic metal layers can be obtained by, for example, thermal evaporation, sputtering, atomic layer deposition, or e-beam evaporation of a plasmonic metal. The plasmonic metal layer is positioned proximal to the photoactive layer. The plasmonic metal layer can be a discontinuous layer having a plurality of noncontiguous regions or layers each having a thickness of less than 10 nm. In certain aspects, the combined surface area of the plurality of noncontiguous regions is up to 70%, 60%, 50%, 40%, 30%, or less of the surface area of the photoactive layer. In other aspects, the plasmonic metal layer can be a continuous layer. In preferred aspects, the continuous plasmonic metal layer can have a thickness of at least 10 nm to 20 nm. The plasmonic metal layer can comprise, consist essentially of, or consist of gold, silver, copper, or an alloy thereof. The plasmonic metal layer can be coated onto a substrate. The substrate can be made of a material with sufficient hardness to support the plasmonic metal layer, non-limiting examples of such materials include glass, quartz, polymers such as polyethylene, PET, PEN, polyimide, polyamide, polyamidoimide, polycarbonate (e.g., Lexan™, which is a polycarbonate resin offered by SABIC Innovative Plastics), liquid crystal polymers, cyclic olefin polymers, silicon, metal, etc. The substrate can be any surface of an article of manufacture (e.g., the walls of a container, the walls of a reactor such as a water-splitting reactor, a front or back electrode of a photovoltaic device, etc.). In certain instances, the thickness of the photoactive layer can be 100 nm to 500 nm, preferably, 200 nm to 400 nm, or more preferably 250 nm to 350 nm. The photoactive layer can be a titanium dioxide layer, a zinc oxide layer, or a cadmium sulfide layer, or a layer having any combination of titanium dioxide, zinc oxide, and/or cadmium sulfide. In preferred aspects, the photoactive layer can be a titanium dioxide layer having anatase, rutile, brookite, or a mixture thereof. In some instances, the photoactive layer is anatase. In other aspects, the photactive layer is a mixed phase of anatase and rutile. The ratio of anatase to rutile can be 1.5:1 to 10:1. In certain embodiments, the photoactive layer can be impregnated with a metal or metal particles can be deposited on the surface of the photoactive layer. The impregnated metal or metal particles can include palladium, silver, platinum, gold, rhodium, ruthenium, rhenium, iridium, nickel, or copper, or any combinations or oxides or alloys thereof. The amount of impregnated metal or metal particles that can be used can be up to 5 wt. % (e.g., 0.1, 0.5, 2, 3, 4, 5 wt. %) of the total weight of the photoactive layer. In certain instances, the plasmonic metal layer can be in direct contact with the photoactive layer or at least one intermediate/interlayer can be positioned between the plasmonic metal layer and the photoactive layer. In preferred aspects, the intermediate layer can be a metal oxide layer such as silicon dioxide (SiO₂).

Also disclosed is an aqueous composition comprising that includes the multi-layered photocatalyst of the present invention. In addition to water, the composition can include a sacrificial agent (e.g., methanol, ethanol, propanol, butanol, iso-butanol, methyl tert-butyl ether, ethylene glycol, propylene glycol, glycerol, or oxalic acid, or any combination thereof, with ethylene glycol or glycerol being preferred). The aqueous composition can include 0.1 to 2 g/L of the photocatalyst.

In yet another embodiment of the present invention, there is disclosed a water-splitting system for generating hydrogen from water. The system can include a container/reaction vessel comprising water and any one of the multi-layered photocatalysts or aqueous compositions of the present invention. In certain preferred embodiments, the photocatalyst can be coated onto the surface of the reaction vessel's walls such that the water-splitting reaction takes place at the interface between the water and the vessel's walls. In other instances, the photocatalyst can be included on a substrate or support structure that is then placed into the water of the reaction vessel. Multiple photocatalysts on such substrates (e.g., at least 2, 3, 4, 5, 6, 7, 8, 9, 10, or more) can be used to maximize the production of H₂ and O₂. The substrates can each be positioned or angled at determined locations to maximize the interaction of light with the photoactive layer and/or the metal plasmonic layer. A light source can be included in the system. The light source can be sunlight or an artificial light source, or a combination thereof. The artificial light source can be an ultraviolet lamp or a Xenon lamp.

In still another embodiment of the present invention, there is disclosed a method for producing oxygen (O₂) and hydrogen (H₂) from water, the method comprising obtaining the aqueous composition or systems of the present invention and subjecting the water having the photocatalyst to a light source for a sufficient period of time to produce O₂ and H₂ from the water. Non-limiting hydrogen production rates include 5×10⁻⁴ to 2×10⁻³ mol/g_{Catal} min, preferably 8×10⁻⁴ to 2×10⁻³ mol/g_{Catal} min, or more preferably 1×10⁻³ to 2×10⁻³ mol/g_{Catal} min. The reaction conditions can include sunlight or an ultraviolet light luminous flux of 5 to 7 mW/cm² and 30 mL or a combination thereof. The aqueous composition, in preferred aspects can include a sacrificial agent. The amount of sacrificial agent can be modified or tuned as desired. In some aspects, the aqueous composition is a 5 vol % glycerol aqueous solution. The ratio of H₂ to CO₂ produced can be 8 to 50.

In another aspect of the present invention, there is disclosed a method for enhancing the electric field produced at an interface between a photoactive layer having a thickness of 10 nanometers (nm) to 1000 nm and a plasmonic metal layer having a thickness of 2 nm to 20 nm and having surface plasmon resonance properties in response to ultra-violet and/or visible light. The method can include positioning the plasmonic metal layer proximal to the photoactive layer. As discussed throughout this specification, the thickness of the plasmonic metal layer can preferably be 4 nm to 12 nm, more preferably 6 nm to 10 nm, and most preferably from 7 nm to 9 nm or about 8 nm. The plasmonic metal layer and the photoactive layer can each have the same features as those discussed above and throughout this specification.

In yet another aspect of the present invention there is disclosed a photovoltaic cell comprising any one of the photocatalysts of the present invention. The photovoltaic cell can include a front electrode, a back electrode, and an active layer positioned there between (See, for example, FIG. 3). The active layer can be the combination of the photoactive layer and the plasmonic metal layer of the present invention. A transparent substrate can be used to support the front electrode, active layer, and back electrode stack. In preferred instances, the arrangement of the photovoltaic cell can be: a transparent substrate; a front electrode deposited on a surface of the transparent substrate; an active layer deposited on a surface of the front electrode opposite the substrate; and a back electrode deposited on a surface of the active layer opposite the front electrode.

Also disclosed in the context of the present invention are embodiments 1-50. Embodiment 1 is a photocatalyst comprising: a photoactive layer having a thickness of 10 nanometers (nm) to 1000 nm; and a plasmonic metal layer having a thickness of 2 nm to 20 nm and having surface plasmon resonance properties in response to ultra-violet and/or visible light, wherein the plasmonic metal layer is positioned proximal to the photoactive layer. Embodiment 2 is the photocatalyst of embodiment 1, wherein the plasmonic metal layer has a thickness of 4 nm to 12 nm, preferably 6 nm to 10 nm, more preferably from 7 nm to 9 nm, or most preferably about 8 nm. Embodiment 3 is the photocatalyst of embodiment 2, wherein the plasmonic metal layer has a thickness of 7 nm to 9 nm. Embodiment 4 is the photocatalyst of any one of embodiments 1 to 3, wherein the plasmonic metal layer is a discontinuous layer having a plurality of noncontiguous regions each having a thickness of less than 10 nm. Embodiment 5 is the photocatalyst of embodiment 4, wherein the combined surface area of the plurality of noncontiguous regions is up to 30% of the surface area of the photoactive layer. Embodiment 6 is the photocatalyst of embodiment 1, wherein the plasmonic metal layer has a thickness of at least 10 nm and is a continuous layer. Embodiment 7 is the photocatalyst of any one of embodiments 1 to 6, wherein the plasmonic metal layer is gold, silver, copper, or an alloy thereof. Embodiment 8 is the photocatalyst of any one of embodiments 1 to 7, wherein the plasmonic metal layer is supported by a substrate. Embodiment 9 is the photocatalyst of any one of embodiments 1 to 8, wherein the thickness of the photoactive layer is 100 nm to 500 nm, preferably, 200 nm to 400 nm, or more preferably 250 nm to 350 nm. Embodiment 10 is the photocatalyst of any one of embodiments 1 to 9, wherein the photoactive layer is a titanium dioxide layer, a zinc oxide layer, or a cadmium sulfide layer, or a layer having any combination of titanium dioxide, zinc oxide, and/or cadmium sulfide. Embodiment 11 is the photocatalyst of embodiment 10, wherein the photoactive layer is a titanium dioxide layer having anatase, rutile, brookite, or a mixture thereof. Embodiment 12 is the photocatalyst of embodiment 11, wherein the titanium dioxide is anatase. Embodiment 13 is the photocatalyst of embodiment 11, wherein the titanium dioxide is a mixed-phase comprising anatase and rutile. Embodiment 14 is the photocatalyst of embodiment 13, wherein the ratio of anatase to rutile is 1.5:1 to 10:1. Embodiment 15 is the photocatalyst of any one of embodiments 1 to 14, wherein the photoactive layer is impregnated with a metal selected from palladium, silver, platinum, gold, rhodium, ruthenium, rhenium, iridium, nickel, or copper, or any combinations or oxides or alloys thereof. Embodiment 16 is the photocatalyst of embodiment 15, wherein the amount of metal impregnated into the photoactive layer is less than 5, 4, 3, 2, 1, 0.5 or 0.1 wt. % of the total weight of the photoactive layer. Embodiment 17 is the photocatalyst of any one of embodiments 1 to 16, wherein the plasmonic metal layer is in direct contact with the photoactive layer. Embodiment 18 is the photocatalyst of any one of embodiments 1 to 16, wherein at least one interlayer is positioned between the plasmonic metal layer and the photoactive layer. Embodiment 19 is the photocatalyst of embodiment 18, wherein the interlayer is a metal oxide layer. Embodiment 20 is the photocatalyst of embodiment 19, wherein the interlayer is a SiO₂ layer. Embodiment 21 is the photocatalyst of any one of embodiments 1 to 20, wherein the photocatalyst is capable of catalyzing the photocatalytic electrolysis of water. Embodiment 22 is the aqueous composition comprising the photocatalyst of any one of embodiments 1 to 21. Embodiment 23 is the composition of embodiment 22, comprising 0.1 to 2 g/L of the photocatalyst. Embodiment 24 is the composition of any one of embodiments 22 to 23, further comprising a sacrificial agent. Embodiment 25 is the composition of embodiment 24, wherein the sacrificial agent is methanol, ethanol, propanol, butanol, iso-butanol, methyl tert-butyl ether, ethylene glycol, propylene glycol, glycerol, or oxalic acid, or any combination thereof. Embodiment 26 is the composition of embodiment 25, wherein the sacrificial agent is ethylene glycol or glycerol or a combination thereof.

Embodiment 27 is a water-splitting system for generating hydrogen from water, the system comprising a reaction vessel comprising water and any one of the photocatalysts of embodiments 1 to 21 or any one of the compositions of embodiments 22 to 26. Embodiment 28 is the water-splitting system of embodiment 27, wherein the photocatalyst is attached to the surface of the reaction vessel that is in contact with the water. Embodiment 29 is the water-splitting system of embodiment 28, wherein the photoactive layer of the photocatalyst is the outer most layer that is in contact with water or is not in direct contact with the surface of the reaction vessel. Embodiment 30 is the water-splitting system of any one of embodiments 27 to 29, further comprising a light source for irradiating the water. Embodiment 31 is the water-splitting system of embodiment 30, wherein the light source is sunlight or an artificial light source, or a combination thereof. Embodiment 32 is the water-splitting system of embodiment 31, wherein the artificial light source is an ultraviolet lamp or a Xenon lamp.

Embodiment 33 is a method for producing oxygen (O₂) and hydrogen (H₂) from water, the method comprising obtaining the aqueous composition of any one of embodiments 22 to 26 or the system of any one of embodiments 27 to 32, and subjecting the water having the photocatalyst to a light source for a sufficient period of time to produce O₂ and H₂ from the water. Embodiment 34 is the method of embodiment 33, wherein the hydrogen production rate is from 5×10⁻⁴ to 2×10⁻³ mol/g_{Catal} min, preferably 8×10⁻⁴ to 2×10⁻³ mol/g_{Catal} min, or more preferably 1×10⁻³ to 2×10⁻³ mol/g_{Catal} min. Embodiment 35 is the method of embodiment 34, wherein the reaction conditions include an ultraviolet light luminous flux of 5 to 7 mW/cm² and 30 mL of 5 vol. % glycerol aqueous solution. Embodiment 36 is the method of any one of embodiments 33 to 35, wherein the light source is sunlight or an artificial light source, or a combination thereof. Embodiment 37 is the method of embodiment 36, wherein the artificial light source is an ultraviolet lamp or a Xenon lamp. Embodiment 38 is the method of any one of embodiments 33 to 37, wherein the ratio of H₂ to CO₂ produced is from 8 to 50.

Embodiment 39 is a method for enhancing the electric field produced at an interface between a photoactive layer having a thickness of 10 nanometers (nm) to 1000 nm and a plasmonic metal layer having a thickness of 2 nm to 20 nm and having surface plasmon resonance properties in response to ultra-violet and/or visible light, the method comprising positioning the plasmonic metal layer proximal to the photoactive layer. Embodiment 40 is the method of embodiment 39, wherein the plasmonic metal layer has a thickness of 4 nm to 12 nm, preferably 6 nm to 10 nm, more preferably from 7 nm to 9 nm, or most preferably about 8 nm. Embodiment 41 is the method of embodiment 40, wherein the plasmonic metal layer has a thickness of 7 nm to 9 nm. Embodiment 42 is the method of any one of embodiments 39 to 41, wherein the plasmonic metal layer is a discontinuous layer having a plurality of noncontiguous regions each having a thickness of less than 10 nm. Embodiment 43 is the method of embodiment 42, wherein the combined surface area of the plurality of noncontiguous regions is up to 30% of the surface area of the photoactive layer. Embodiment 44 is the method of embodiment 39, wherein the plasmonic metal layer has a thickness of at least 10 nm and is a continuous layer. Embodiment 45 is the method of any one of embodiments 39 to 44, wherein the plasmonic metal layer is gold, silver, copper, or an alloy thereof. Embodiment 46 is the method of any one of embodiments 39 to 45, wherein the photoactive layer is a titanium dioxide layer, a zinc oxide layer, or a cadmium sulfide layer, or a layer having any combination of titanium dioxide, zinc oxide, and/or cadmium sulfide. Embodiment 47 is the method of any one of embodiments 39 to 46, wherein the plasmonic metal layer is in direct contact with the photoactive layer. Embodiment 48 is the method of any one of embodiments 39 to 46, wherein at least one interlayer is positioned between the plasmonic metal layer and the photoactive layer. Embodiment 49 is the method of embodiment 48, wherein the interlayer is a metal oxide layer. Embodiment 50 is the method of embodiment 49, wherein the interlayer is a SiO₂ layer.

The following includes definitions of various terms and phrases used throughout this specification.

The term “proximal” when used in the phrase “wherein the plasmonic metal layer is positioned proximal to the photoactive layer” refers to the plasmonic metal layer being in direct in contact with the photoactive layer (See, for example, FIG. 1A) or within a sufficient distance of the photoactive layer such that the electric field produced by the plasmonic metal layer, when subjected to ultraviolet and/or visible light, assists in the promotion of excited electrons and holes to the surface of the photoactive layer. In preferred instances, the sufficient distance between the plasmonic metal layer and the photoactive layer is up to 15 nm. This can allow, for example, an intermediate or interlayer being positioned between the plasmonic metal layer and the photoactive layer (See, for example, FIG. 1B).

“Water splitting” or any variation of this phrase describes the chemical reaction in which water is separated into oxygen and hydrogen.

The terms “inhibiting” or “reducing” or “preventing” or “avoiding” or any variation of these terms, when used in the claims and/or the specification includes any measurable decrease or complete inhibition to achieve a desired result. By way of example, reducing the likelihood for an excited electron in the conductive band to recombine with a hole in the valence band encompasses situations where a decrease in the number of electron/hole recombination events occurs or an increase in the time it takes for an electron/hole recombination event to occur such that the increase in time allows for the electron to reduce hydrogen ions rather than to recombine with its corresponding hole.

“Effective” or any variation of this term, when used in the claims or specification, means adequate to accomplish a desired, expected, or intended result.

“Nanostructure” refers to an object or material in which at least one dimension of the object or material is equal to or less than 1000 nm (e.g., one dimension is 1 to 1000 nm in size). In a particular aspect, the nanostructure includes at least two dimensions that are equal to or less than 1000 nm (e.g., a first dimension is 1 to 1000 nm in size and a second dimension is 1 to 1000 nm in size). In another aspect, the nanostructure includes three dimensions that are equal to or less than 1000 nm (e.g., a first dimension is 1 to 1000 nm in size, a second dimension is 1 to 1000 nm in size, and a third dimension is 1 to 1000 nm in size). The shape of the nanostructure can be of a wire, a particle, a sphere, a rod, a tetrapod, a hyper-branched structure, or mixtures thereof.

The term “about” or “approximately” are defined as being close to as understood by one of ordinary skill in the art. In one non-limiting embodiment the terms are defined to be within 10%, preferably within 5%, more preferably within 1%, and most preferably within 0.5%.

The term “substantially” and its variations are defined to include ranges within 10%, within 5%, within 1%, or within 0.5%.

The terms “wt. %”, “vol. %”, or “mol. %” refers to a weight, volume, or molar percentage of a component, respectively, based on the total weight, the total volume of material, or total moles, that includes the component. In a non-limiting example, 10 grams of component in 100 grams of the material is 10 wt. % of component.

The use of the words “a” or “an” when used in conjunction with any of the terms “comprising,” “including,” “containing,” or “having” in the claims or the specification may mean “one,” but it is also consistent with the meaning of “one or more,” “at least one,” and “one or more than one.”

The photocatalysts and photoactive materials of the present invention can “comprise,” “consist essentially of,” or “consist of” particular components, compositions, ingredients, etc. disclosed throughout the specification. With respect to the transitional phase “consisting essentially of,” in one non-limiting aspect, a basic and novel characteristic of the photoactive catalysts and materials of the present invention is the thickness of the plasmonic metal layer being between 2 nm and 20 nm, preferably, 4 nm to 12 nm, more preferably 6 nm to 10 nm, most preferably from 7 nm to 9 nm or about 8 nm.

Other objects, features and advantages of the present invention will become apparent from the following figures, detailed description, and examples. It should be understood, however, that the figures, detailed description, and examples, while indicating specific embodiments of the invention, are given by way of illustration only and are not meant to be limiting. Additionally, it is contemplated that changes and modifications within the spirit and scope of the invention will become apparent to those skilled in the art from this detailed description.

### BRIEF DESCRIPTION OF THE DRAWINGS

FIGS. 1A-D: (A) Schematic of a cross-sectional view of a photocatalyst of the present invention where a photoactive layer is in direct contact with a plasmonic metal layer; (B) Schematic of a cross-sectional view of a photocatalyst of the present invention where a photoactive layer is in indirect contact with a plasmonic layer (e.g., a third intermediate/interlayer is positioned between the photoactive layer and the plasmonic metal layer); (C) a top view of a continuous plasmonic metal layer supported by a substrate; and (D) a top view of a discontinuous plasmonic metal layer having a plurality of noncontiguous regions supported by a substrate.

FIGS. 2A-B: Schematic of a water splitting system of the present invention where the photoactive catalyst is (A) coated on the surface of the reaction container's walls and (B) coated on a substrate that is placed inside the reaction container.

FIG. 3: Schematic of an organic photovoltaic cell incorporating a photocatalyst of the present invention.

FIG. 4: Scanning electron microscope (SEM) image of Au plasmonic metal layers thermally evaporated on glass substrates. Layers having a thickness below 10 nm are discontinuous layers. Layers having a thickness above 10 nm are continuous layers.

FIGS. 5A-B: (A) Optical absorption as function of wavelength of Au plasmonic layers with different thicknesses; and (B) % R as function of wavelength of Au plasmonic layers with different thicknesses.

FIGS. 6A-B: (A) Hydrogen production of TiO₂ photocatalyst as function of Au plasmonic metal layer thickness (reaction conditions include Quartz reactor, Xenon lamp with UV flux (300-380 nm) about 5 mW/cm², 30 mL H₂O with 5 vol. % glycerol); (B) Hydrogen production of TiO₂ photocatalyst as function of Au plasmonic metal layer thickness under UV and visible light radiation.

FIGS. 7A-B: (A) Optical absorption of non-plasmonic platinum layer; and (B) Hydrogen production of TiO₂ photocatalysts as function of plasmonic Au layer and non-plasmonic Pt layer thicknesses (reaction conditions include Quartz reactor, Xenon lamp with UV flux (300-380 nm)˜5 mW/cm², 30 mL H₂O with 5 vol. % glycerol).

FIGS. 8A-B: Optical simulations (Finite Difference Time Domain (FDTD)) of TiO₂ on Au plasmonic films by using commercial software, COMSOL Multiphyisics version 4.4. COMSOL use finite element method (FEM) to solve Maxwell's equations for specific electromagnetic wave condition and gives electrical field intensity (|E|²) as an output. The incident electromagnetic field was assumed to be 1 V/m, with wavelength of incident electromagnetic field set to be at 500 nm and polarized in y-direction.

FIG. 9: (A) EF enhancement at interface of Au plasmonic metal layer and TiO₂ photoactive layer as function of Au layer thickness; and (B) Hydrogen production from TiO₂ photocatalysts on Au plasmonic metal layers (Circles equals rates under experimental conditions. Square equals rates normalized to the EF enhancement obtained from the optical simulations).

### DETAILED DESCRIPTION OF THE INVENTION

While hydrogen-based energy from water has been proposed by many as a solution to the current problems associated with carbon-based energy (e.g., limited amounts and fossil fuel emissions), the currently available technologies are expensive, inefficient, and/or unstable. The present application provides a solution to these issues. The solution is predicated on the discovery that plasmonic metal layers having a certain thickness can dramatically enhance hydrogen production rates from a water-splitting reaction. Without wishing to be bound by theory, it is believed that when a plasmonic metal layer having a thickness of 2 nm to 20 nm, preferably 4 nm to 12 nm, more preferably 6 nm to 10 nm, most preferably from 7 nm to 9 nm or about 8 nm, is positioned proximal to a photoactive layer, the electric field produced by the plasmonic metal layer, when subjected to UV and/or visible light, increases the charge carrier life time of the electrons and holes produced in the photoactive layer. This leads to an increase in hydrogen production through reduction of hydrogen ions rather than an electron-hole recombination event. As illustrated in non-limiting embodiments in the Examples, a critical range of thickness for the plasmonic metal layer has been identified to achieve this increase in hydrogen production. In a most preferred embodiment, the photoactive layer is a TiO₂ layer and the plasmonic metal layer is a gold layer, with the highest hydrogen production being obtained with a gold plasmonic layer having a thickness of 7 nm to 9 nm, with the peak production being about a thickness of 8 nm.

These and other non-limiting aspects of the present invention are discussed in further detail in the following sections.

### A. Photoactive Catalysts

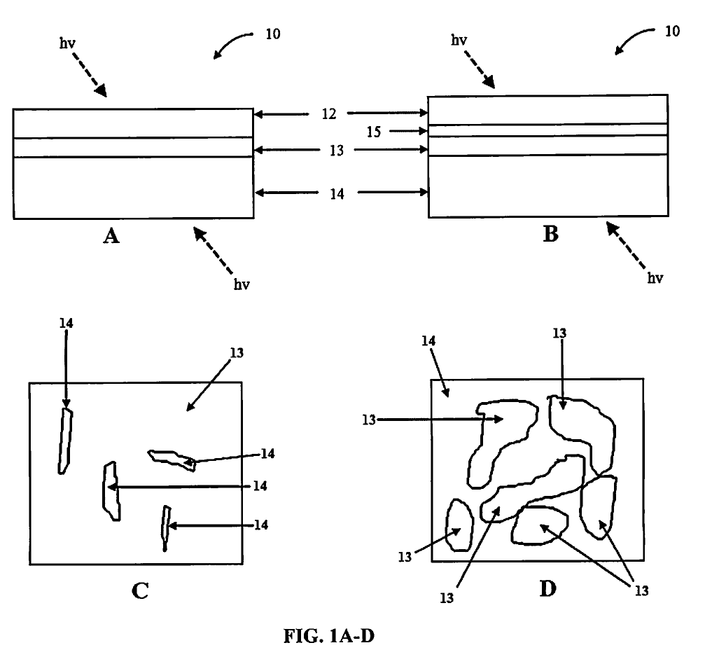

Referring to FIGS. 1(A)-(D), multi-layered photoactive catalysts 10 of the present invention are illustrated through non-limiting schematics. By way of example, the photoactive catalysts 10 can include a photoactive layer 12 that is coated directly onto a plasmonic metal layer 13 (FIG. 1(A). Alternatively, a third layer (also referred to as intermediate layer or interlayer) 15 can be positioned between the photoactive layer 12 and plasmonic metal layer 13 (FIG. 1(B)). Although not shown, fourth, fifth, sixth, or more layers can also be positioned between the photoactive layer 12 and plasmonic metal layer 13. When an intermediate layer 15 is present, the thickness of this layer 15 and the materials of the layer can be selected to ensure that the electric field produced by the plasmonic layer 13 still exerts its effects on the photoactive layer 12. In preferred instances, the distance between the photoactive layer 12 and plasmonic metal layer is 0 nm (i.e., direct contact) or within 20 nm or less. The photoactive catalysts can be supported by a support 14. In a preferred instance, the plasmonic metal layer 13 is positioned closer to the support 14 then the photoactive layer 12. When the support 14 is transparent, then light (hν) can contact the photoactive layer 12 and the plasmonic layer 13 in either direction as illustrated in FIGS. 1(A) and (B). When the support material 14 is opaque or reflective, then the light (hν) typically contacts the photoactive layer 12 first and then the plasmonic metal layer 13. The light (hν) can be ultraviolet light (280 nm to 400 nm) or visible light (400 nm to 700 nm). In preferred instances, a combination of ultraviolet light and visible light can be used to maximize electron/hole formations and H₂ and O₂ production from the water splitting reaction.

One of the discoveries of the present invention is that the LSPR or plasmonic resonance effect of the plasmonic metal layer 13 can be optimized by modifying or tuning the thickness of this layer 13. As illustrated in non-limiting aspects in the Examples, a thickness range of 2 nm to 20 nm leads to an optimization in the LSPR. It was further discovered that a thickness of 10 nm and greater leads to a continuous layer 13. A non-limiting illustration of the continuous layer 13 is provided in FIG. 1(C), which is a top view of the layer 13. In FIG. 1(C), although portions of the substrate 14 can be seen through gaps or regions in which the plasmon metal layer 13 is not present, it is continuously connected around these gaps or regions. Although not illustrated, the continuous layer 13 can be made where no such gaps or regions exist. When the thickness of the plasmonic metal layer is less than 10 nm, then the layer can exhibit a discontinuous layer morphology, which is illustrated in FIG. 1(D), a top view of layer 13. In FIG. 1(D), the discontinuous plasmonic metal layer 13 is represented by a plurality of noncontiguous regions 13 each having a thickness of less than 10 nm.

Still further, the photactive layer 13 can be impregnated with or coated with additional materials that further enhance the efficiency of the water-splitting reaction and ultimate production of H₂ and/or O₂. By way of example, the photoactive layer 13 can be impregnated with metals or oxides or alloys thereof or can be coated with metal nanostructures or oxides or alloys thereof. Non-limiting examples of such metals include palladium, silver, platinum, gold, rhodium, ruthenium, rhenium, iridium, nickel, or copper, or any combinations or oxides or alloys thereof.

1. Materials Used

The photoactive layer 12 can be made from any type of photoactive material that is capable of producing excited elections in response to ultraviolet and/or visible light. In preferred embodiments, the photoactive material can include titanium dioxide, zinc oxide, or cadmium sulfide, or any combinations thereof. In particular instances, the photoactive material is titanium dioxide. Titanium dioxide can be in the form of three phases, the anatase phase, the rutile phase, and the brookite phase. Anatase and rutile phases have a tetragonal crystal system, whereas the brookite phase has an orthorhombic crystal system. While anatase and rutile both have a tetragonal crystal system consisting of TiO₆ octahedra, their phases differ in that anatase octahedras are arranged such that four edges of the octahedras are shared, while in rutile, two edges of the octahedras are shared. These different crystal structures resulting in different density of states may account for the different efficiencies observed for transfer of charge carriers (electrons) in the rutile and anatase phases and the different physical properties of the catalyst. For example, anatase is more efficient than rutile in the charge transfer, but is not as durable as rutile. Each of the different phases can be purchased from various manufactures and supplies (e.g., Titanium (IV) oxide anatase Nano powder and Titanium (IV) oxide rutile Nano powder in a variety of sizes and shapes can be obtained from Sigma-Aldrich® Co. LLC (St. Louis, Mo., USA) and from Alfa Aesar GmbH & Co KG, A Johnson Matthey Company (Germany)); all phases of titanium dioxide from L.E.B. Enterprises, Inc. (Hollywood, Fla. USA)). They can also be synthesized using known sol-gel methods (See, for example, Chen et al., Chem. Rev. 2010 Vol. 110, pp. 6503-6570, the contents of which are incorporated herein by reference).

The plasmonic metal layer 13 can be made from any type of material that includes LSPR or plasmonic resonance effects when exposed to ultraviolet and/or visible light. In preferred instances, the material can be metal selected from gold, silver, copper, or an alloy thereof.

The intermediate layer 15 can be made from any type of material. Preferably, the material would be of a kind that enhances the efficiency of the water-splitting reaction and ultimate production of H₂ and/or O₂. In one non-limiting aspect, the intermediate layer 15 can be silicon dioxide (SiO₂), aluminum oxide (Al₂O₃), or alkaline earth metal oxides such magnesium oxide (MgO), calcium oxide (CaO), or the like. The thickness of this interlayer can be up to 20 nm, preferably 6 nm or most preferably 2 nm.

The substrate 14 can be any type of material that is capable of supporting the photoactive layer 12, the plasmonic layer 13, and/or any intermediate layers 15. Non-limiting examples of materials that can be used for the substrate include glass, quartz, polymers such as polyethylene, PET, PEN, polyimide, polyamide, polyamidoimide, polycarbonate (e.g., Lexan™, which is a polycarbonate resin offered by SABIC Innovative Plastics), liquid crystal polymers, cyclic olefin polymers, silicon, metal, etc. The substrate 14 can be any surface of an article of manufacture (e.g., the walls of a container, the walls of a reactor such as a water-splitting reactor, etc.).

2. Process of Making the Photocatalysts

Non-limiting examples for making photocatalysts are disclosed in the Examples of the present specification. Generally, the following steps can be used to manufacture catalysts of the present invention.

The plasmonic metal layer 13 can be coated onto the substrate 14 with processes known to those having ordinary skill in the art. Non-limiting examples include thermal evaporation, sputtering, atomic layer deposition, or e-beam evaporation. In some preferred aspects, the substrate surface can be first cleaned, for example, by ultra-sonication in acetone, ethanol, and/or deionized (DI) water. Subsequently, the plasmonic metal layer 13 can be deposited by thermal evaporation in a vacuum chamber. The deposition can be done at room temperature with a constant deposition rate of 0.1 A°/s to 0.5 A°/s, preferably about 0.2 A°/s. Subsequently, the photoactive layer 12, or the intermediate layer 15 if one is desired, can be coated onto the surface of the plasmonic metal layer 13 with processes known to those having ordinary skill in the art. If an intermediate layer 15 is first deposited onto the plasmonic metal layer 13, then the same type of coating process used for the intermediate layer 15 can be used to apply the photoactive layer 12 to the intermediate layer 15. Non-limiting processes include drop casting, dip coating, spin coating, blade coating, or spray coating. The thickness of the photoactive layer 12 and/or the intermediate layer 15 can be modified or tuned as desired by modifying the amount of materials used and/or the timing of the coating process. In preferred instances, the thickness of the photoactive layer 12 can be 10 nm to 1000 nm, more preferably 100 nm to 500 nm, still more preferably, 200 nm to 400 nm, or most preferably 250 nm to 350 nm. If used, the thickness of the intermediate layer 15 can be up to 10 nm.

### B. Water-Splitting System

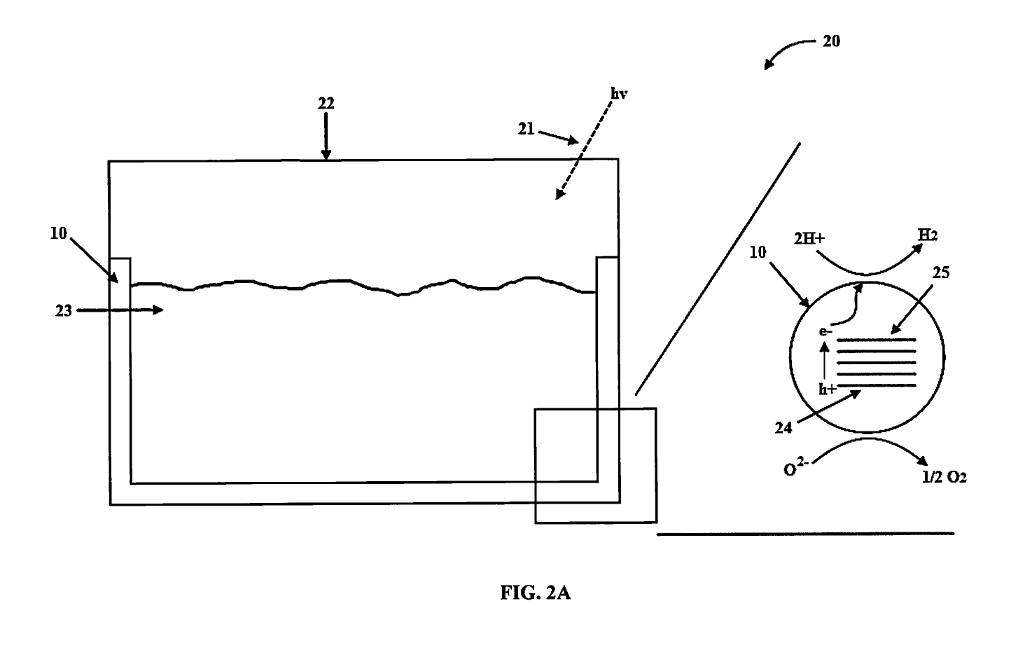

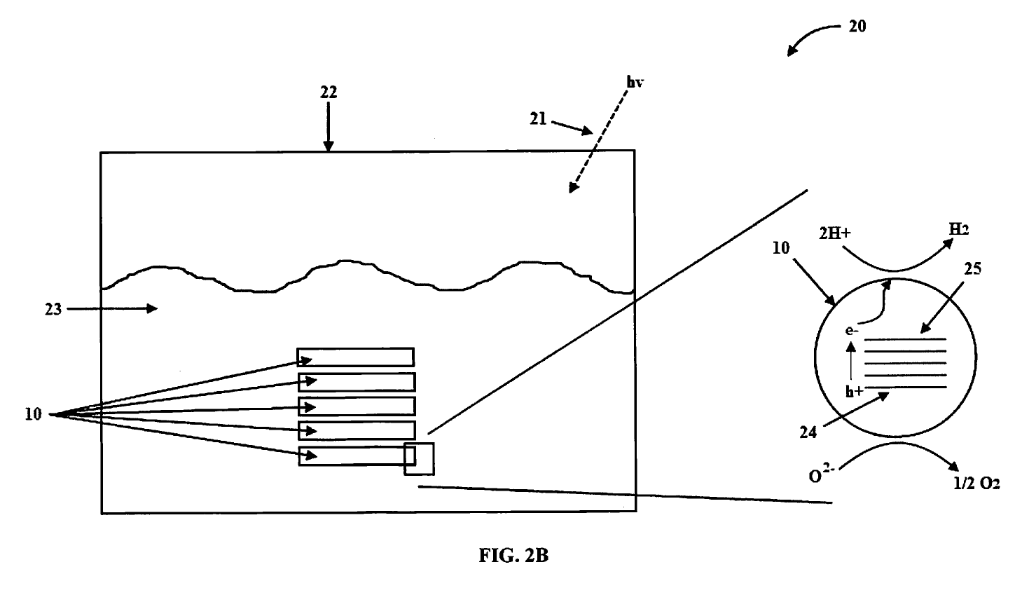

Referring to FIGS. 2A and B, a non-limiting representation of a water-splitting system 20 of the present invention is provided. The systems each include a photocatalyst 10, a light source 21, and container or reaction vessel 22 that can be used to hold aqueous solutions or water 23. Although not shown, the system 20 can also include at least one inlet for the aqueous solution/water 23 and at least one or more outlets for produced hydrogen and oxygen formed during the water-splitting reaction. In one embodiment, the photocatalyst 10 can be coated onto the walls of the container 22 (See FIG. 2A), preferably with the plasmonic metal layer 13 contacting the container 22 wall and the photoactive layer 12 contacting the water 23. In this instance, the substrate 14 is the walls of the container 22. Alternatively, and in another embodiment, the photocatalyst can be supported by a substrate 14 and then placed into the water (See FIG. 2B). In certain instances, a plurality of supported photocatalysts 10 can be used to maximize hydrogen and oxygen production. To maximize efficiency, the substrate can be transparent, thereby allowing for light to contact both the photoactive layer 12 and the plasmonic metal layer 13 in different directions.

In either instance, the container 22 can be a transparent, translucent or even opaque such as those that can magnify light (e.g., opaque container having a pinhole(s)). The photocatalyst 10 can be used to split water to produce H₂ and O₂. The light source 21 can includes either one of or both of visible and (400-600 nm) and ultraviolet light (280-400). The light can excite the photoactive layer 12 to excite an electron in the valence band 24 to the conductive band 25. The light can also excite the metal plasmon resonance layer 13 such that an electric field is generated. The excited electrons (e⁻) leave a corresponding hole (h⁺) when the electrons move to the conductive band. The excited electrons (e⁻) are used to reduce hydrogen ions to form hydrogen gas, and the holes (h⁺) are used to oxidize oxygen ions to oxygen gas. The hydrogen gas and the oxygen gas can then be collected and used in down-stream processes. Due to the electric field produced by the metal plasmonic layer 13, excited electrons (e⁻) are more likely to be used to split water before recombining with a hole (h⁺) than would otherwise be the case. Notably, the system 20 does not require the use of an external bias or voltage source. Further, the efficiency of the system 20 allows for one to avoid or use minimal amounts of a sacrificial agent such as methanol, ethanol, propanol, butanol, isobutanol, methyl tert-butyl ether, ethylene glycol, propylene glycol, glycerol, oxalic acid, or any combination thereof. In certain aspects, however, 0.1 to 10 w/v %, or preferably 2 to 7 w/v %, of a sacrificial agent can be included in the aqueous solution. The presence of the sacrificial agent can increase the efficiency of the system 20 by further reducing the likelihood of hole/electron recombination via oxidation of the sacrificial agent by the hole rather than recombination with the excited electron. Preferred sacrificial agents ethylene glycol, glycerol, or a combination thereof is used. In addition to being capable of catalyzing water splitting without an external bias or voltage, the photocatalysts of the present invention may be included in an anode of an electrochemical cell capable of forming oxygen and hydrogen by electrolysis of water. In a non-limiting example, light energy may be provided to a photocell and from the light energy a voltage between the anode and the cathode is produced and water molecules are split to form hydrogen and oxygen. The method can be practiced such that the hydrogen production rate from water can be modified as desired by subjecting the system to various amounts of light energy or light flux. For example, the photoactive catalyst 10 can be used as the anode in a transparent container containing an aqueous solution and used in a water-splitting system. An appropriate cathode can be used such as Mo—Pt cathodes (See, International Journal of Hydrogen Energy, June 2006, Vol. 31, issue 7, pages 841-846, the contents of which are incorporated herein by reference) or MoS₂ cathodes (See, International Journal of Hydrogen Energy, February 2013, Vol. 38, issue 4, pages 1745-1757, the contents of which are incorporated herein by reference).

### C. Photovoltaic Application

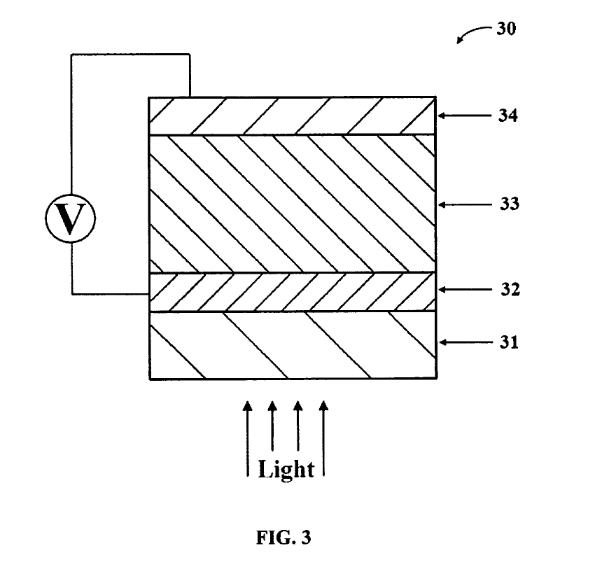

In addition to water splitting applications, the photocatalysts of the present invention can also be used in other applications that utilize excited electrons. By way of example, the photocatalysts can be used in a photovoltaic cell. Referring to FIG. 3, this figure is a cross-sectional view of a non-limiting photovoltaic cell that incorporates the photocatalyst of the present invention. The photovoltaic cell 30 can include a transparent substrate 31, a front electrode 32, an active layer 33, and a back electrode 34 which can also act as substrate 14. The active layer 33 includes the photoactive layer 12 and plasmonic metal layer 13 of the present invention. Preferably, the photoactive layer 12 can be positioned next to the front electrode 32 and the plasmonic metal layer 13 can be positioned next to the back electrode 34. Alternatively, the photoactive layer 12 can be positioned next to the back electrode 34 and the plasmonic metal layer 13 can be positioned next to the front electrode 32. Additional materials, layers, and coatings (not shown) known to those of ordinary skill in the art can be used with photovoltaic cell 30. Generally speaking, the photovoltaic cell 30 can convert light into usable energy by: (a) photon absorption to produce excitons; (b) exciton diffusion; (c) charge transfer; and (d) charge separation and transportation to the electrodes.

The front electrode 32 can be used as a cathode or anode depending on the set-up of the circuit. It is stacked on the substrate 31. The front electrode 32 can be made of a transparent or translucent conductive material. Alternatively, the front electrode 32 can be made of opaque or reflective material. Typically, the front electrode 32 is obtained by forming a film using such a material (e.g., vacuum deposition, sputtering, ion-plating, plating, coating, etc.). Non-limiting examples of transparent or translucent conductive material include metal oxide films, metal films, and conductive polymers. Non-limiting examples of metal oxides that can be used to form a film include indium oxide, zinc oxide, tin oxide, and their complexes such as indium stannate (ITO), fluorine-doped tin oxide (FTO), and indium zinc oxide films. Non-limiting examples of metals that can be used to form a film include gold, platinum, silver, and copper. Non-limiting examples of conductive polymers include polyaniline and polythiophene. Also, the sheet resistance of the front electrode 32 is typically 10 Ω/sq or less. Further, the front electrode 32 may be a single layer or laminated layers formed of materials each having a different work function.

The back electrode 34 can be used as a cathode or anode depending on the set-up of the circuit. This electrode 34 can be made of a transparent or translucent conductive material. Alternatively, it 34 can be made of opaque or reflective material. This electrode 34 can be stacked on the active layer 33. The material used for the back electrode 34 can be conductive. Non-limiting examples of such materials include metals, metal oxides, and conductive polymers (e.g., polyaniline, polythiophene, etc.) such as those discussed above in the context of the front electrode 32. When the front electrode 32 is formed using a material having high work function, then the back electrode 34 can be made of material having a low work function. Non-limiting examples of materials having a low work function include Li, In, Al, Ca, Mg, Sm, Tb, Yb, Zr, Na, K, Rb, Cs, Ba, and the alloys thereof. The back electrode 34 can be a single layer or laminated layers formed of materials each having a different work function. Further, it may be an alloy of one or more of the materials having a low work function and at least one selected from the group consisting of gold, silver, platinum, copper, manganese, titanium, cobalt, nickel, tungsten, and tin. Examples of the alloy include a lithium-aluminum alloy, a lithium-magnesium alloy, a lithium-indium alloy, a magnesium-silver alloy, a magnesium-indium alloy, a magnesium-aluminum alloy, an indium-silver alloy, and a calcium-aluminum alloy.

In some embodiments, the front 32 and back 34 electrodes can be further coated with hole transport or electron transport layers (not shown in FIG. 3) to increase the efficiency and prevent short circuits of the photovoltaic cell 30. The hole transport layer and the electron transport layer can be interposed between the electrode and the active layer 33. Non-limiting examples of the materials that can be used for the hole transport layer include polythiophene-based polymers such as PEDOT/PSS (poly(3,4-ethylenedioxythiophene)-poly(styrene sulfonate)) and organic conductive polymers such as polyaniline and polypyrrole. As for the electron transport layer, it can function by blocking holes and transporting electrons more efficiently.

### EXAMPLES

The present invention will be described in greater detail by way of specific examples. The following examples are offered for illustrative purposes only, and are not intended to limit the invention in any manner. Those of skill in the art will readily recognize a variety of noncritical parameters which can be changed or modified to yield essentially the same results.

### Example 1

### Production and Characterization of Photocatalysts of the Present Invention

The photocatalytic materials were fabricated on glass substrates. First glass slides were cleaned by ultra-sonication in acetone, ethanol and DI water. Thin Au films were deposited on these glass slides by thermal evaporation in a vacuum chamber. The deposition was done at room temperature with a constant deposition rate of 0.2 A°/s. To prepare the photocatalyst, anatase TiO₂ (supplier: Hombikat) with an average particle size of about 7 nm and BET surface area of about 320 m²/g was impregnated with PdCl₂ salt solution. Excess water was evaporated to dryness under constant stirring with slow heating at 80° C. The dried photocatalysts was calcined at 350° C. for 5 hours. The resulting photo-catalysts with 0.4 wt % Pd loading on anatase TiO₂ had an average particle size of about 10-12 nm and BET surface area of approximately 120 m²/g. Similarly, comparative devices using non-plasmonic metal films (platinum (Pt) films) were prepared, where the Pt was deposited using Radio Frequency (RF) sputtering.

The TiO₂ photocatalysts were coated on the Au films by the spin coating method. A TiO₂ dispersion (1.5 wt. %) was prepared in ethanol and spun coated on the Au thin film at 500 rpm for 20 sec. The coating process was repeated 5 times and the thin films were heated at 90° C. for 20 min to remove ethanol.

UV-VIS absorbance spectra of the catalysts were collected over the wavelength range of 250-2000 nm on a Thermo Fisher Scientific spectrophotometer equipped with praying mantis diffuse reflectance accessory. Absorbance (A) and reflectance (R) of the samples were measured.

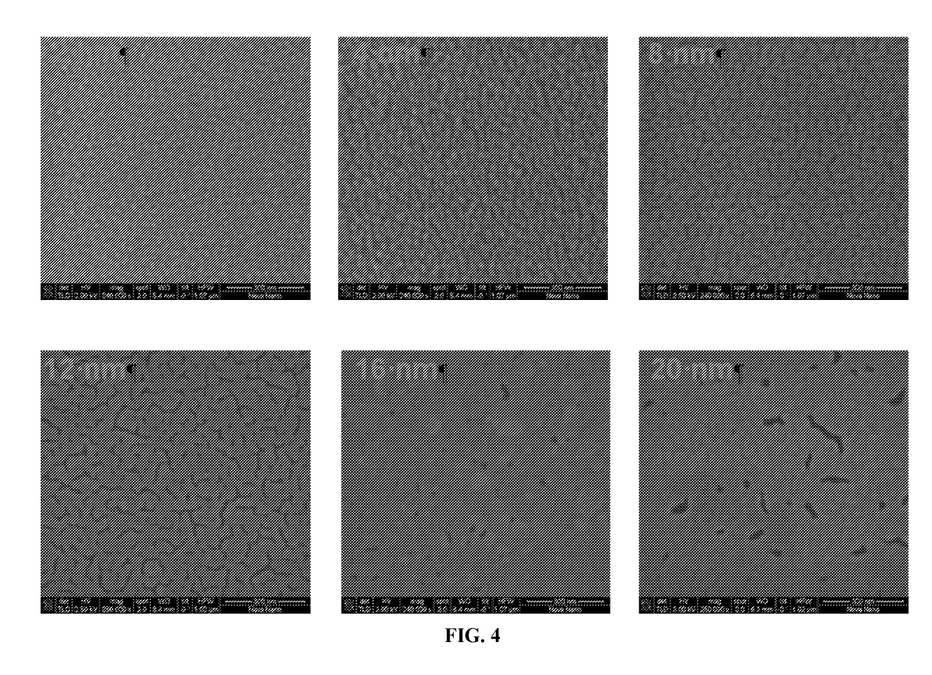

FIG. 4 shows a high resolution scanning electron microscopy (HRSEM) images of the Au plasmonic metal films with thicknesses of 2, 4, 8, 12, 16 and 20 nm deposited on glass slides. A Volmer-Weber growth is seen (islands growth) for the 2 and 4 nm Au films. See Kaiser, N. Review of the fundamentals of thin-film growth, Appl. Opt. 2002, 41, 3053-3060; Orr et al., A Model for Strain-Induced Roughening and Coherent Island Growth, EPL (Europhysics Letters) 1992, 19, 33; Seel et al., Tensile stress evolution during deposition of Volmer-Weber thin films, Journal of Applied Physics 2000, 88, 7079-7088; Zhang et al., Atomistic Processes in the Early Stages of Thin-Film Growth, Science 1997, 276, 377-383. With increasing thickness these islands composed of Au, particles start to coalesce. The average size and irregularity of the islands increase with increasing film thickness. The formation of worm-like particles is the direct evidence of aggregation of Au NPs due to touching and merging of adjacent particles. The formation of inter-links between the coalescences of Au NPs was greatly enhanced as the film continued growing, and a continuous film was eventually formed as the film thickness reached about 12 nm.

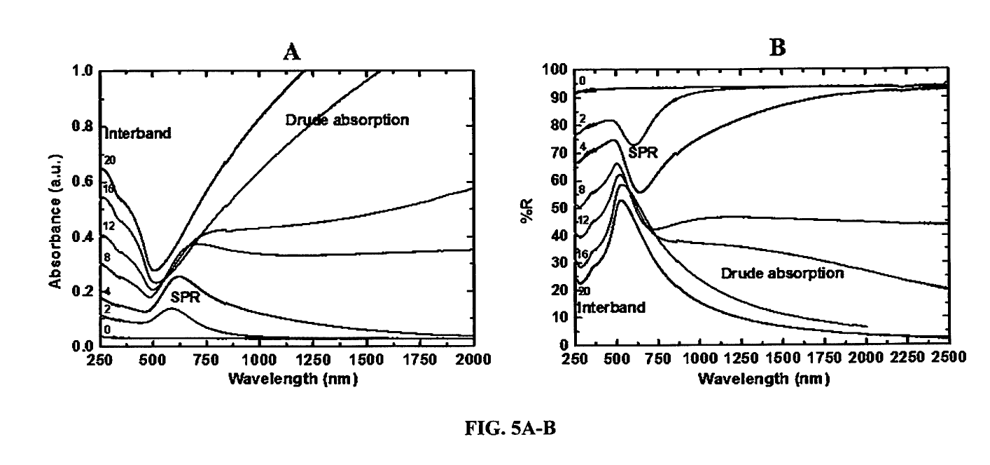

This unique island-like structure discontinuous film of noble metals leads to interesting optical properties. FIG. 5(A) shows the absorption spectra of Au films as a function of thickness. As seen in FIG. 5(A) there are three regions of absorption. Absorption due to inter-band transitions are observed at ˜260 and 380 nm. The localized surface plasmon resonance LSPR for 2 nm Au films is located around 580 nm and is red shifted with increasing thickness up to 8 nm Au films. From FIG. 4 Au discontinuous island regions are between 10 and 20 nm for the 2 nm thick layer and up to 30 nm for the 4 nm thick layer. This is observed in the absorption spectra in FIG. 5 where a shift from 590 nm (2 nm-thick layer) to 640 nm (8 nm-thick layer) is seen. For films thicker than 8 nm, the formation of interlinks (conductive percolation paths) between the Au islands due to their aggregation delocalize the free electrons making a Drude absorption more significant and consequently suppresses LSPR. Reflectance (% R) measurements of the Au films show the same trend as seen in FIG. 5(B).

### Example 2

### Photocatalytic Activity of the Photocatalysts of the Present Invention

Photocatalytic reactions were evaluated in a 190 mL volume quartz reactor. 30 mL of 5 vol % glycerol aqueous solution was used to evaluate the water splitting activity. The coated slides were inserted vertically into the reactor and the reactor was purged with N₂ gas to remove any O₂. The photoreactions were carried out using a Xenon lamp (Asahi spectra MAX-303) at a distance of 9 cm from the reactor with a total UV flux of 5-6 mW/cm² in the 280-380 nm range. Product analysis was performed by gas chromatograph (GC) equipped with thermal conductivity detector (TCD) connected to Porapak Q packed column (2 m) at 45° C. and N₂ was used as a carrier gas.

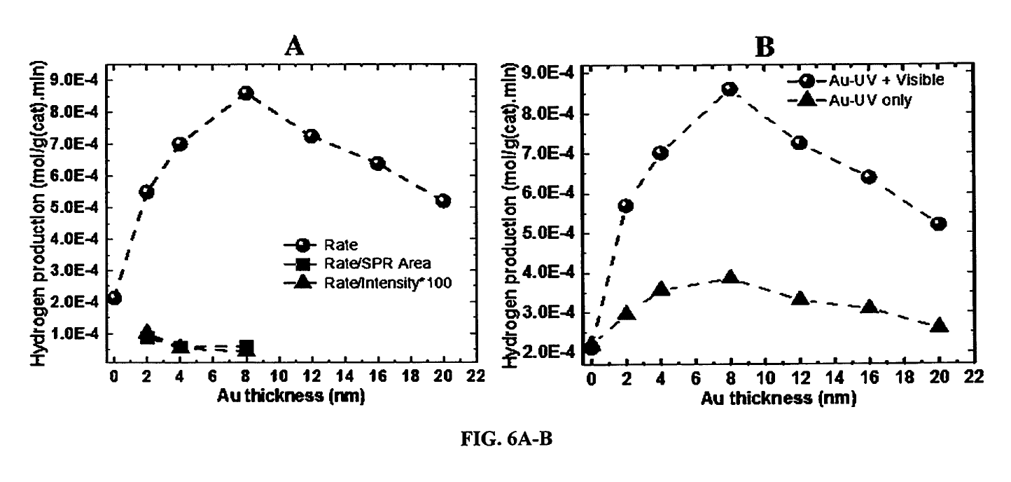

The H₂ production rates of the photocatalysts of the present invention under UV and visible light excitation (280-650 nm) is presented in in FIG. 6. The photocatalytic activity was stable and reproducible. Pure anatase TiO₂ with 0.4 wt. % Pd loading, showed H₂ production rates of abut 200 μmolg⁻¹min⁻¹. When the photocatalysts were coated on Au plasmonic films, it showed a dramatic increase in the hydrogen production rates. With 2 nm thickness, the rates increased 2.5 times to about 550 μmolg⁻¹min⁻¹ and reached a maximum with a thickness of 8 nm. Further increasing the thickness of underlying Au plasmonic film led to a decrease in activity as seen for films from 12 to 20 nm thickness. The trend in H₂ production was similar to the trend seen in LSPR from these Au films as discussed in FIG. 5 where for film thickness greater than 8 nm, the LSPR was suppressed due to the Drude absorption. In other words, normalization of the rates to the LSPR peak area or intensity results in no or negligible changes FIG. 6(A).

The photoreactions were also carried out under UV light only (<400 nm). LSPR is a resonance condition, which is, established when the frequency of incident photons matches the natural frequency of surface electrons oscillating against the restoring force of positive nuclei. By cutting of the visible light, LSPR would be considerably attenuated. As seen in FIG. 6(B), the activity under UV light only was much lower. It is to be noted that the trend of rates under UV is the same with maximum activity for 8 nm Au layers at about 380 μmolg⁻¹min⁻¹. This is a further indication that it is the LSPR property of the Au thin films, which helps improve the activity of the photocatalysts of the present invention, and the LSPR of Au will be active at the resonant frequency.

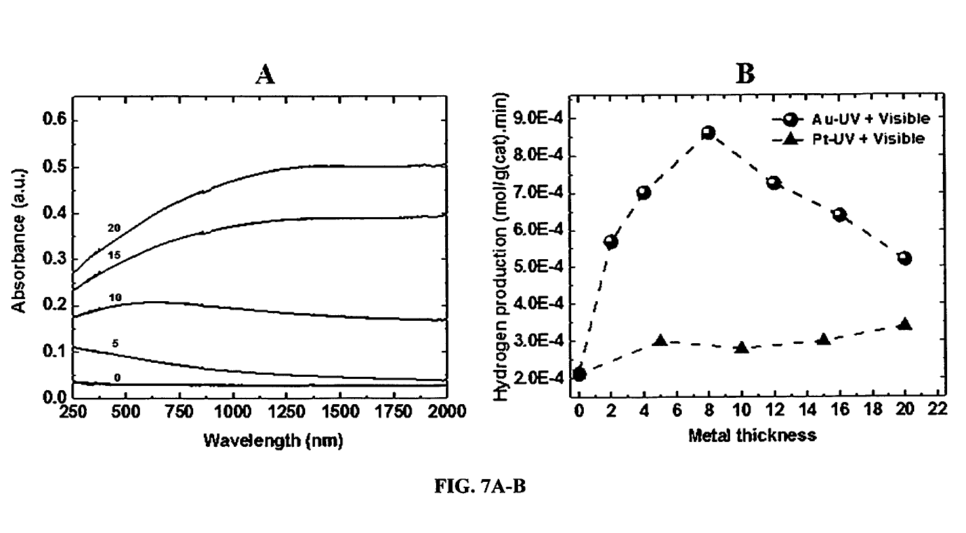

To further confirm the plasmon resonance response has increased the reaction rate rather than increasing the interface between Au and the photoactive catalyst, the plasmonic Au films were replaced with non-plasmonic platinum (Pt) films. Pt films were deposited with different thicknesses from 5 to 20 nm. FIG. 7(A) shows the absorbance of Pt films deposited on quartz where the absence of LSPR is noticed and only the Drude absorption seen for films with thickness above 15 nm. The TiO₂ photocatalyst was coated on top of Pt similar to the Au devices. The photocatalytic activity of these materials is shown in FIG. 7(B) and conducted under identical conditions to those of the Au series. The H₂ production rates showed marginal gradual increase after adding Pt thin film up to 310 μmolg⁻¹min⁻¹ for 20 nm Pt films. The difference in H₂ production rates from Au and Pt films is highlighted in FIG. 7(B).

### Example 3

### Electric Field Enhancement of the Photocatalysts of the Present Invention

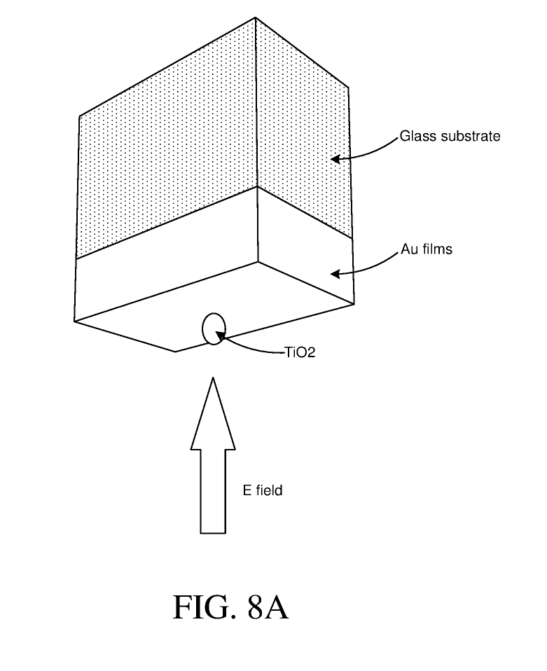

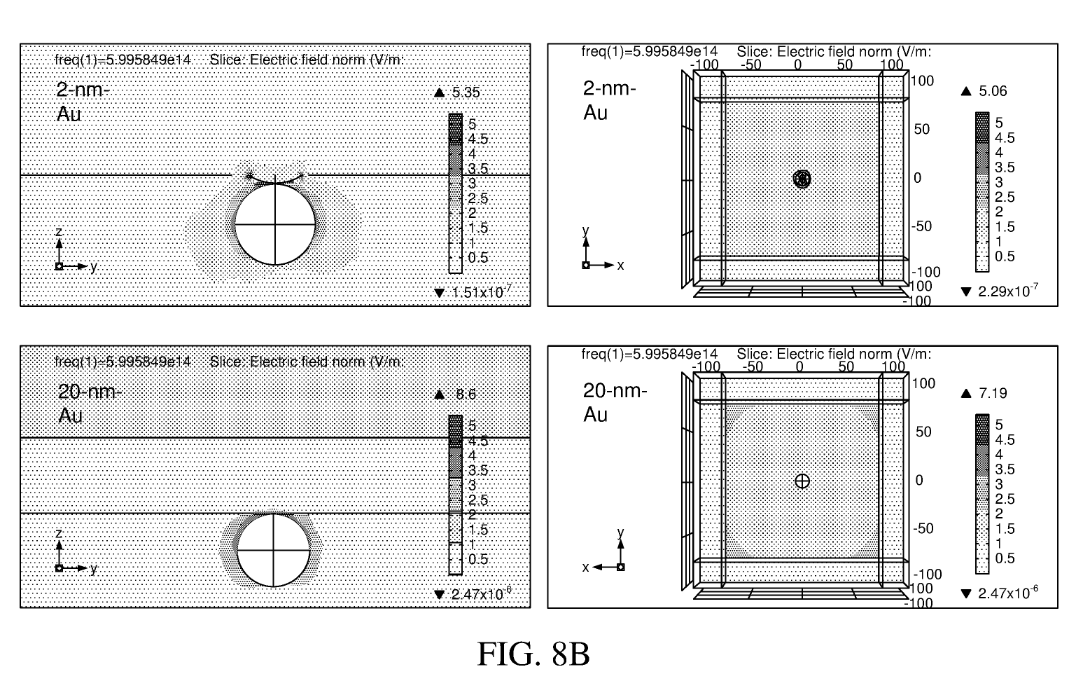

To identify the mechanism of how the LSPR helps enhancing the photocatalytic activity, optical simulations of TiO₂ on Au films as a function of thickness was conducted using commercial software, COMSOL Multiphysics version 4.4., in RF module. COMSOL uses finite element method (FEM) to solve Maxwell's equations for the specific electromagnetic wave condition and gives electrical field intensity (|E|²) as an output. The incident electromagnetic field was taken as 1 V/m; with wavelength of incident, electromagnetic field set to be at 500 nm and polarized in the y-direction. The incident electromagnetic field was set normal to the Au films or glass substrate. Dielectric permittivity of Au was taken from Johnson-Christy report and the Au island size for 2, 4 and 8 nm Au discontinuous films was taken from the collected SEM images while continuous films were assumed for 12, 16 and 20 nm thickness. The optical simulation domain contains nanoparticles in a homogeneous medium, covered with perfectly matched layers (PMLs) at the computational boundaries to avoid any reflection in the domain. The scattering cross-section was also simulated. The results are presented in FIG. 8. The electric filed enhancement in FIG. 8 are for two representative Au films (2 and 20 nm thick) and for two different planes (YZ-plane and XY plane). The XY-plane shows the electric field enhancement in the boundary between TiO₂ nanoparticles (NPs) and Au films while the YZ-plane shows the electric field enhancement along the system TiO₂—Au films-glass substrate. The red color in the figure represents the highest enhancement and the blue the lowest. It can be seen that the enhancement of the electric field was largely isotropic (no much changes in the enhancement in the YX plane when compared to that of the YZ plane). It can also be seen that the effect increased from the 2 nm thick layer of Au to that of 8 nm then decreased again for the 20 nm thick layer.

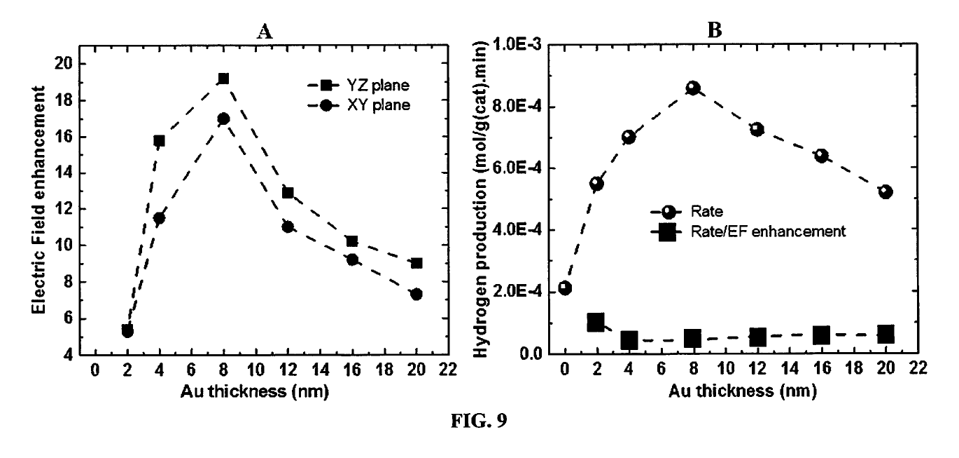

The data of the electric field enhancements for different Au thickness is in FIG. 9(A). With 2 nm Au film (particle size ˜13 nm) the enhancement is about 5 times at the surface of TiO₂ particle. Increasing the Au film thickness dramatically improves the EF enhancement with up to 19 times higher EF for 8 nm films and then starts dropping for thicker films. This was observed in both XY and YZ plane as see in FIG. 9(A). XY-plane shows the electric field enhancement in the boundary between TiO₂ nanoparticles (NPs) and Au films. YZ-plane shows the electric field enhancement along the system (TiO₂—Au films-glass substrate). Notably, a correlation has been observed between the electric field enhancement and the photocatalytic activity. Both of them show similar pattern, with 8 nm-thickness show the highest enhancement.

1. A photocatalyst comprising:
a substrate;
a photoactive layer having a thickness of 10 nanometers (nm) to 1000 nm; and
a plasmonic metal layer having a thickness of 2 nm to 20 nm and having surface plasmon resonance properties in response to ultra-violet and/or visible light,
wherein the plasmonic metal layer is coated on the substrate and the photoactive layer is coated on the plasmonic metal layer.

2. The photocatalyst of claim 1, wherein the plasmonic metal layer has a thickness of 4 nm to 12 nm, preferably 6 nm to 10 nm, more preferably from 7 nm to 9 nm, or most preferably about 8 nm.

3. The photocatalyst of claim 1, wherein the plasmonic metal layer is a discontinuous layer having a plurality of noncontiguous regions each having a thickness of less than 10 nm or a continuous layer having a thickness of at least 10 nm.

4. The photocatalyst of claim 3, wherein the combined surface area of the plurality of noncontiguous regions is up to 30% of the surface area of the photoactive layer.

5. The photocatalyst of claim 1, wherein the plasmonic metal layer is gold, silver, copper, or an alloy thereof.

6. The photocatalyst of claim 1, wherein the plasmonic metal layer is gold.

7. The photocatalyst of claim 1, wherein the thickness of the photoactive layer is 100 nm to 500 nm, preferably, 200 nm to 400 nm, or more.

8. The photocatalyst of claim 1, wherein the photoactive layer is a titanium dioxide layer, a zinc oxide layer, or a cadmium sulfide layer, or a layer having any combination of titanium dioxide, zinc oxide, and/or cadmium sulfide.

9. The photocatalyst of claim 8, wherein the photoactive layer is a titanium dioxide layer having anatase, rutile, brookite, or a mixture thereof, preferably anatase or a mixed-phase comprising anatase and rutile.

10. The photocatalyst of claim 9, wherein the ratio of anatase to rutile is 1.5:1 to 10:1.

11. The photocatalyst of claim 1, wherein the photoactive layer is impregnated with a metal that is less than 5, 4, 3, 2, 1, 0.5 or 0.1 wt. % of the total weight of the photoactive layer selected from palladium, silver, platinum, gold, rhodium, ruthenium, rhenium, iridium, nickel, or copper, or any combinations or oxides or alloys thereof.

12. The photocatalyst of claim 1, wherein the plasmonic metal layer is in direct contact with the photoactive layer.

13. The photocatalyst of claim 1, wherein at least one interlayer is positioned between the plasmonic metal layer and the photoactive layer.

14. The photocatalyst of claim 13, wherein the interlayer is a metal oxide layer, preferably a SiO₂ layer.

15. The photocatalyst of claim 1, wherein the photocatalyst is capable of catalyzing the photocatalytic electrolysis of water.

16. An aqueous composition comprising the photocatalyst of claim 1.

17. A water-splitting system for generating hydrogen from water, the system comprising a reaction vessel comprising water and any one of the photocatalysts of claim 1.

18. A method for enhancing the electric field produced at an interface between a photoactive layer having a thickness of 10 nanometers (nm) to 1000 nm and a plasmonic metal layer having a thickness of 2 nm to 20 nm and having surface plasmon resonance properties in response to ultra-violet and/or visible light, the method comprising coating the plasmonic layer on a substrate, and subsequently coating the plasmonic metal layer on the photoactive layer.

19. The method of claim 18, wherein the plasmonic metal layer has a thickness of 4 nm to 12 nm, preferably 6 nm to 10 nm, more preferably from 7 nm to 9 nm, or most preferably about 8 nm.

20. The method of claim 18, wherein the plasmonic metal layer is a discontinuous layer having a plurality of noncontiguous regions each having a thickness of less than 10 nm or a continuous layer having a thickness of at least 10 nm.
